(19) United States
(12) Patent Application Publication
(10) Pub. No.: US 2006/0289887 A1
(43) Pub. Date: Dec. 28, 2006

(54) Surface mount light emitting diode (LED) assembly with improved power dissipation

(75) Inventors: Thong Bui, Pinellas Park, FL (US); Michiko Shimada, Tampa, FL (US); Israel J. Morejon, Tampa, FL (US); Waleed Rusheidat, Odessa, FL (US); Paul Neathway, Tierra Verde, FL (US)

Correspondence Address: MILLER JOHNSON SNELL CUMMISKEY, PLC, 800 CALDER PLAZA BUILDING, 250 MONROE AVE N W, GRAND RAPIDS, MI, 49503-2250, US

(73) Assignee: Jabil Circuit, Inc.

(21) Appl. No.: 11/165,900

(22) Filed: Jun. 24, 2005

(51) Int. Cl. H01L 33/00

(52) U.S. Cl. 257/99

(57) ABSTRACT

A high performance LED (402) and associated semiconductor package (400) advantageously utilizes an integrated heat sink (408) for purposes of power dissipation. At a next level of assembly, (500, 600) the semiconductor package (400) is electromechanically coupled to a printed circuit board (300). The printed circuit board (300) has a cavity (208) with thermal contact pad (308) disposed therein and connected to a metal back plane (106). During electromechanical coupling, the heat sink (408) is thermally coupled to the metal back plane (106) via the thermal contact pad (308). During operation, the thermal coupling of the heat sink (408) to the metal back plane, also referred to as a thermal mass reservoir (106) operates to increase the effective thermal mass of the integrated heat sink (408) and thereby provide enhanced power dissipation and heat transfer away from the high performance LED device (402).

### FIELD OF INVENTION

The present invention relates generally to Light Emitting Diodes and particularly to high performance Light Emitting Diodes. Specifically, the present invention relates to a surface mount Light Emitting Diode and associated assembly techniques providing enhanced thermal performance and power dissipation.

### BACKGROUND

Light Emitting Diodes, hereinafter referred to as LEDs are well known in the art. These semiconductor devices, using well established techniques, are specially constructed to outwardly release a large number of photons during operation. When properly directed and/or focused, these photons are visible to the human eye as light. Depending on the particular semiconductor material selected and the frequency of oscillation associated with the released photons, the color of the light produced by the LED can be altered and/or selected. As such, LEDs are now available in a wide variety colors.

Up until recently; however, LEDs were in general too expensive to use in most lighting applications because they are constructed with advanced and sometimes exotic semiconductor materials. In addition, they tended to exhibit marginal output performance (i.e., brightness) when compared to traditional lighting alternatives. But as the prices of both semiconductor materials and manufacturing techniques have declined in recent decades, LEDs have steadily become a more cost effective lighting option when compared to conventional incandescent lamps. Moreover, as the availability of high performance LEDs offering improved brightness has increased, LEDs look increasingly attractive as a viable lighting alternative for a widening range of lighting applications.

As will be appreciated, one of the main advantages exhibited by the traditional LED is its efficiency. When compared to traditional lighting systems, a much higher percentage of an LEDs input current goes to the generation of light, as opposed to the generation of heat. Said another way, traditional (i.e., low power) LEDs typically generate very little heat during operation.

High performance LEDs, on the other hand, while capable of generating light with luminance intensities ranging from 1400-2000 millicandelas (mcd), at 75 milliamps (mA) and 175 milliamps (mA) respectively, are nevertheless much less efficient than their low power counterparts. As such, high performance LEDs generally require special steps to assure sufficient power dissipation and heat transfer away from the semiconductor device comprising the LED. In accordance with prior teaching, one solution suggests the integration of a heat sink device into the semiconductor package that houses the high performance LED. Such devices have, in the past, been commercially available by contacting Bivar, Inc. at their offices located at 4-T Thomas, Irvine, Calif. 92618. While this approach claims to provide power dissipation in a range from 525-450 milliwatts (mW), there are nevertheless a number of higher power applications requiring greater power dissipation than that offered by the adoption of integrated heat sink methodologies.

It is therefore desirable to have a high performance LED that enjoys the performance benefits of prior art systems employing integrated heat sinks, while exhibiting enhanced thermal performance and power dissipation at a next level of assembly.

### BRIEF DESCRIPTION OF THE DRAWINGS

FIG. 1 shows a cross-sectional view of a printed circuit board (PCB) in accordance with the present invention;

FIG. 2 shows a cross-sectional view of the PCB of FIG. 1;

FIG. 3 shows an isometric view of the PCB of FIG. 2;

FIG. 4 shows a cross-sectional view of the PCB next level of assembly in accordance with the present invention;

FIG. 5 shows a cross-sectional view of an electronics package in accordance with the present invention;

FIG. 6 shows a cross-sectional view of a first embodiment of the LED assembly of the present invention;

FIG. 7 shows a cross-sectional view of a second embodiment of the LED assembly of the present invention; and

FIG. 8 shows yet another embodiment of the LED assembly of the present invention.

### DETAILED DESCRIPTION OF THE PREFERRED EMBODIMENT

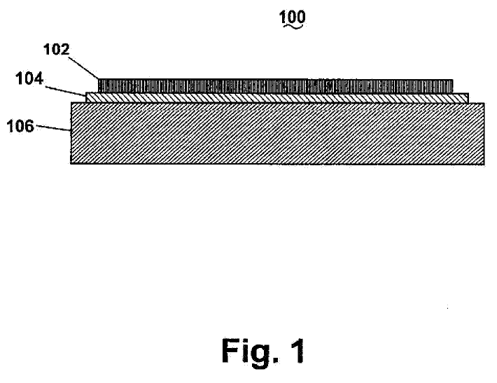

The present invention provides for a high performance surface mount light emitting diode (LED) that is mechanically and thermally coupled to a next level of assembly in order to provide enhanced power dissipation and heat transfer away from the high performance LED. FIG. 1 shows a cross-sectional view of a printed circuit board (PCB) in accordance with the present invention. The PCB 100 consists of a metallization layer 102, a dielectric layer 104, and a metal back plane 106. As will be appreciated by those skilled in the art, the dielectric layer 104 can be any of the well known and non-conducting materials commonly used in PCB substrate manufacture. Disposed on a first surface of the dielectric substrate 104 is a thin metallization layer 102. This thin layer of metal, generally copper, silver, gold or other precious metal, is used to provide conductive traces or circuit paths for electronic components that are affixed to the PCB. Finally, metal back plane 106 is another layer of metal affixed to the second surface of dielectric layer 104. Such a back plane is well known in the electronics art and serves several useful purposes in the construction of the printed circuit board 100. In accordance with a preferred embodiment, the back plane 106 comprises a layer of copper affixed to the dielectric 104 by means of available techniques such as, for example, thermal cladding and the like. As will be appreciated by those skilled in the art, back plane 106 can be used to provide a common point of reference potential for circuitry connected to PCB 100. In addition, it may be used as a thermal mass for purposes of supporting heat transfer and/or power dissipation for components connected to PCB 100.

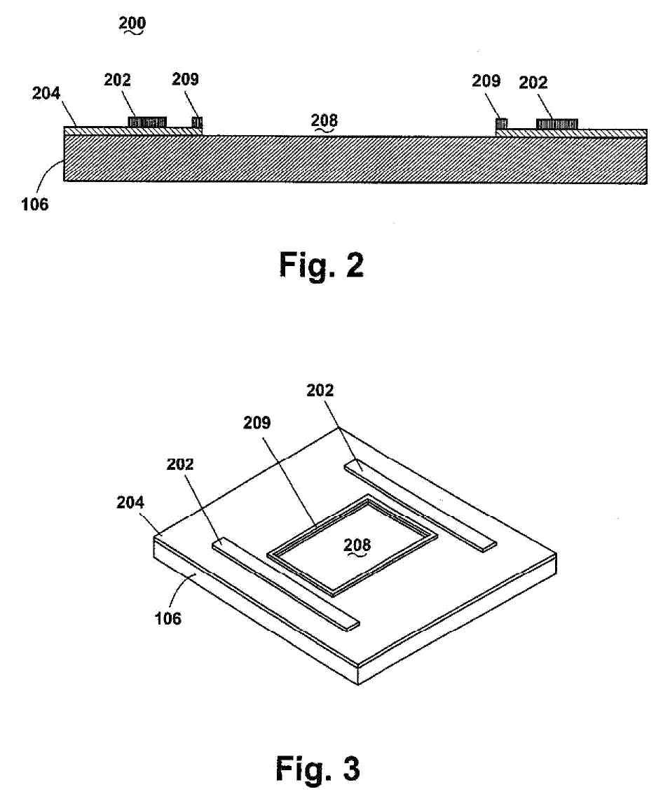

FIG. 2 shows a cross-sectional view of the PCB 100 of FIG. 1. Using well know semiconductor and printed circuit board manufacturing techniques, such as masking and etching, the printed circuit board 100 of FIG. 1 can be altered as shown in FIG. 2. The process of etching away or exposing specific sections of the PCB layered construct, while masking other sections to keep them intact, is done for purposes of PCB customization. By way of example, and with reference to FIG. 2, specific sections of metallization layer 102 have been etched away to define surface features such as conductive circuit traces 202 and solder dam 209. In addition, specific sections of dielectric material have been removed by means of available techniques, such as, for example, laser ablation, to produce a void or cavity 208 in dielectric substrate 204, and to expose the copper backplane layer 106 at predefined locations on PCB 200.

FIG. 3 shows an isometric view of PCB 200 of FIG. 2. As will be appreciated from this vantage, the void 208 has a solder dam 209 disposed around its perimeter or periphery. As previously mentioned, solder dam 209 is a surface feature of PCB 200, created by selectively etching the metallization layer 102 of PCB 100 in order to produce features such as conductive circuit paths 202 and solder dam 209. As will be appreciated after review hereof, solder dam 209 is employed as both a reservoir for thermally conductive material and as a barrier to assure electrical separation between conductive circuit paths 202 and subsequent levels of assembly and/or production.

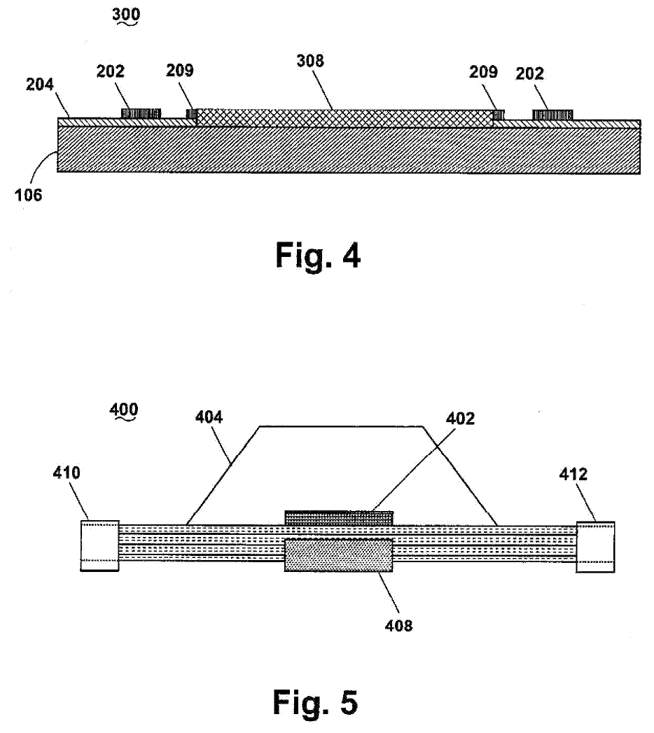

FIG. 4 provides a cross-sectional view of PCB next level of assembly 300. Once again, using well know semiconductor and printed circuit board manufacturing techniques, such as, for example, masking, metal deposition, and etching, the printed circuit board 200 of FIG. 2 can be modified as shown in FIG. 4. As depicted, the void 208 previously created in the dielectric material layer 204 of FIG. 2 is now filled, in FIG. 4, by any one of a number of well known metal deposition techniques. Pursuant to the operations described in association with FIG. 4, a thermally conductive material, such as gold, silver, copper, lead, solder, or any combination thereof is deposited in the void 208. In accordance with the preferred embodiment, the thermally conductive material fills the void 208 within the dielectric material layer 204 to create a thermal contact pad 308. Of note, during deposition, the conductive material comprising thermal contact pad 308 is held in relative position by solder dam 209. As such, solder dam 209 provides a barrier that prevents thermal contact pad 308 from making electrical contact with conductive circuit traces 202. Of further note, the conductive material comprising thermal contact pad 308 will exhibit a measure of thermal conductivity that will, in great measure, influence the rate at which heat transfers to and through thermal contact pad 308. For this reason, it is advisable to select materials that exhibit measures of thermal conductivity that are at least equal to and preferably greater than the thermal conductivity exhibited by materials comprising either heat sink 408 or back plane 106.

In accordance with a preferred embodiment, the thermal contact pad is disposed at least partially within the dielectric material layer 204 of PCB 300. As depicted in FIG. 4, the thermal contact pad 308 is accessible from the top surface of PCB 300 and is substantially coplanar with solder dam 209. In further accordance with a preferred embodiment, the thermal contact pad 308 is both thermally and mechanically coupled to metal back plane 106, also referred to herein as thermal mass reservoir 106. This mechanical connection may be achieved by means of direct metal-to-metal contact or, in the alternative, by means of either soldering or by application of thermally conductive adhesives as are known in the art.

FIG. 5 shows a cross-sectional view of a high performance LED 402, housed in an electronics package 400, such as for example, a semiconductor package. As shown, the electronics package 400 has a dielectric substrate 406 that physically supports the high performance LED 402. The LED 402 is electrically connected via conductive pathways (not shown) to electronic terminals 410 and 412, respectively. In accordance with the preferred embodiment, terminal 410 is the device Cathode, while terminal 412 is the device Anode. A dome lens 404 consisting of epoxy, or similar translucent material, covers the LED for protection, and focuses emitted light energy for purposes of enhanced visibility. The semiconductor package 400 also employs a heat sink 408 that is integrated into the semiconductor package 400. The heat sink 408 operates to draw heat away from the LED 402 during operation. While such devices claim to provide superior power dissipation, there are several high power applications requiring greater power dissipation than currently offered via heat sink methodologies alone. By way of example, and not by way of limitation, some such applications include, but are not limited to, high power transistors, high current LEDs, bare die devices with wire bonding, and the like. It is precisely for any such device that operates at electrical current flows exceeding 200 milliamps or produces thermal energy exceeding 1 Watt that the present invention is intended.

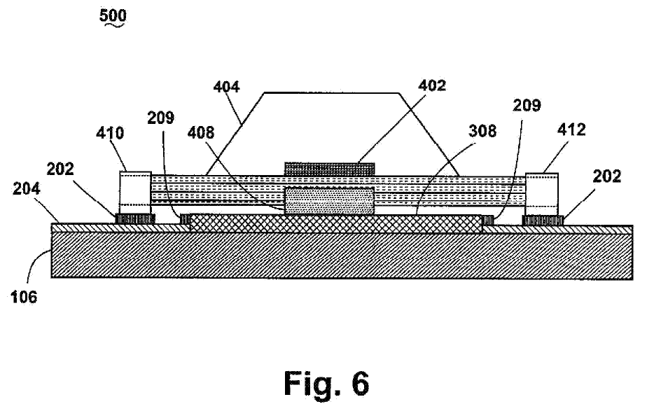

In accordance, FIG. 6 shows a cross-sectional view of the surface mount LED assembly 500 of the present invention. As shown, the LED assembly 500 comprises the electronics package 400 of FIG. 5 coupled to the next level of assembly 300 of FIG. 4. In accordance with a preferred embodiment, the electronics package 400 is electromechanically coupled to the next level of assembly 300 to complete the LED assembly 500 of the present invention. As will be appreciated, the electromechanical coupling occurs when the Cathode 410 and Anode 412 of the electronics package 400 are electrically connected to the conductive circuit paths 202 by any of a number of well known electrical fastening techniques. Options may include, but are by no means limited to, soldering, either conventional, reflow, or ultrasonic, and the use of adhesives, such as conductive adhesives. Mechanical coupling is achieved, in part, by the direct contact that occurs between heat sink 408 and thermal contact pad 308 when the LED assembly 500 is assembled.

After assembly, the device 500 exhibits improved power dissipation and enhanced heat transfer characteristics due, in part, to the direct mechanical and thermal coupling between heat sink 408 and thermal contact pad 308. As will be appreciated after the review of FIG. 6, the LED device 402, heat sink 408, thermal contact pad 308, and thermal mass reservoir 106 are thermally coupled, one to another, and define a heat transfer path from the LED 402 to the thermal mass reservoir 106. Since thermal mass reservoir 106 has a measure of thermal mass greater than that exhibited by heat sink 408, thermal mass reservoir 106 has greater heat storage/power dissipation capacity than does heat sink 408. By thermally couplin heat sink 408 to the thermal mass reservoir 106, the LED assembly 500 of the present invention operates to effectively increase the overall thermal mass available for power dissipation purposes. It is this increase in available thermal mass that provides LED assembly 500 with enhanced thermal performance and improved power dissipation capability, when compared to competitive solutions.

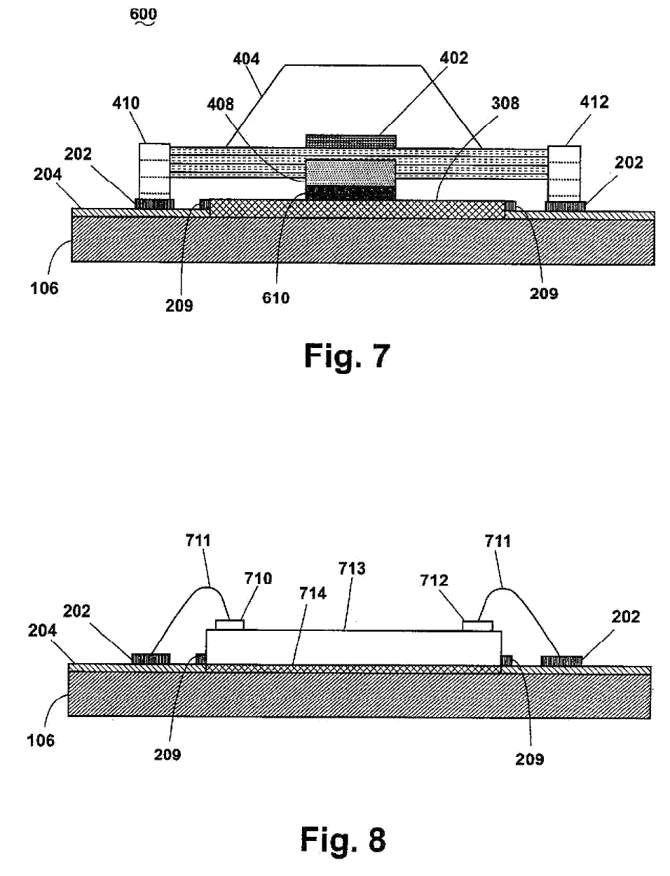

FIG. 7 shows a cross-sectional view of a second embodiment of the LED assembly of the present invention. As in FIG. 6, the LED device 402, heat sink 408, thermal contact pad 308, and thermal mass reservoir 106 of LED assembly 600 are thermally coupled, one to another, and define a heat transfer path from the LED 402 to the thermal mass reservoir 106. Because the heat transfer path of the LED assembly 600 has a larger thermal mass than does heat sink 408, it exhibits greater heat storage and power dissipation capacity than does heat sink 408, when operating in isolation. By thermally coupling heat sink 408 to the thermal mass reservoir 106, the LED assembly 600 of the present invention operates to effectively increase the overall thermal mass available for power dissipation purposes.

By way of differentiation, it will be noted that thermal contact pad 308 of FIG. 7 is mechanically coupled to heat sink 408 by any of a number of well known fastening techniques. Options include, but are not limited to, soldering, either conventional, reflow, or ultrasonic, and the use of adhesives, such as thermally conductive adhesives. In accordance with the present embodiment, LED assembly 600 employs a layer 610 of thermally conductive adhesive in order to assure both mechanical and thermal coupling between heat sink 408 and thermal contact pad 308.

FIG. 8 shows yet another embodiment of the LED assembly of the present invention. By way of differentiation, the LED assembly 700 of FIG. 8 utilizes a bare die wire bonding assembly technique whereby the LED circuit 713 is electromechanically coupled to the next level of assembly without the use of a semiconductor package. As will be appreciated, the electromechanical coupling occurs when Cathode 710 and Anode 712 of LED circuit 713 are electrically connected to the conductive circuit paths 202 by means of wire bonds 711. Mechanical coupling is achieved, in part, by the direct contact that occurs between LED circuit 713 and thermal contact pad 714 when the back side of the LED die 713 is bonded to the next level of assembly. As will be noted, the thermal contact pad 714 of FIG. 8 is disposed substantially within dielectric layer 204 of the PCB next level of assembly and is shown to be substantially coplanar with the top surface of dielectric substrate 204. As previously noted, solder dam 209 is employed as a barrier to assure electrical separation between conductive circuit traces 202 and the thermal contact pad 714. In accordance with the preferred embodiment, thermal contact pad 714 consists of a layer of solder. Notwithstanding, it will be appreciated by those skilled in the art that other thermally conductive materials may be substituted therefore, without departing from the spirit of the present invention.

After assembly, the device 700 exhibits improved power dissipation and enhanced heat transfer characteristics due, in part, to the direct mechanical and thermal coupling between LED circuit 713 and thermal contact pad 714. As will be appreciated after the review of FIG. 8, the LED device 713, thermal contact pad 714, and thermal mass reservoir 106 are thermally coupled, one to another, and define a heat transfer path from LED 713 to the thermal mass reservoir 106. Since thermal mass reservoir 106 has a measure of thermal mass greater than that exhibited by either LED circuit 713 or thermal contact pad 714, the thermal mass reservoir 106 exhibits superior heat storage/power dissipation capacity. By thermally coupling LED circuit 713 to the thermal mass reservoir 106, the LED assembly 700 of the present invention operates to effectively increase the overall thermal mass available for power dissipation purposes. It is this increase in available thermal mass that provides LED assembly 700 with enhanced thermal performance and improved power dissipation capability, when compared to competitive solutions.

Based upon the embodiments discussed herein, it will be readily apparent to those skilled in the art that the present invention is not limited to the above embodiments but may be changed and/or modified without departing from the spirit and scope of the invention as described. For example, while the integrated heat sink 408 is depicted as being substantially coplanar with Cathode and Anode terminals 410 and 412 of semiconductor package 400, it will be appreciated by those skilled in the art that heat sink 408 may, in fact, be disposed within the dielectric material layer 406 of semiconductor package 400, and as such, exhibit a substantially coplanar orientation with the bottom surface of dielectric substrate 406. In addition, the heat transfer path of LED assemblies 500, 600, and 700 may comprise differing conductive materials. By way of example, and not by way of limitation, heat sink 408 and metal back plane 106 may be made of copper, while thermal contact pad 308 may comprise a different conductive material altogether. As will be appreciated by those skilled in the art, by selecting conductive materials having superior measure of thermal conductivity, the heat transfer path of LED assemblies 500, 600, and 700 can be made more efficient.

1. A surface mount Light Emitting Diode (LED) assembly comprising:
an electronics package comprising:
an LED device; and
a heat sink thermally coupled to the LED device; and
a next level of assembly comprising:
a dielectric substrate having a first and a second surface and a cavity disposed within the substrate;
a thermal contact pad disposed within the cavity; and
a thermal mass reservoir disposed on the second surface of the dielectric substrate, said thermal mass reservoir being directly connected to the thermal contact pad,
wherein the LED device is thermally coupled to the thermal mass reservoir when the integrated heat sink is connected to the thermal contact pad of the next level of assembly.

2. The surface mount LED assembly of claim 1 further comprising a barrier feature disposed around a perimeter of the cavity.

3. The surface mount LED assembly of claim 1, wherein the electronics package is selected from a group consisting of semiconductor packages.

4. The surface mount LED assembly of claim 1, wherein the dielectric substrate is a printed circuit board (PCB).

5. The surface mount LED assembly of claim 4, wherein the thermal mass reservoir is a metal mass affixed to the printed circuit board.

6. The surface mount LED assembly of claim 1, wherein the thermal contact pad is substantially coplanar with a first metallization layer disposed on the first surface of the dielectric substrate.

7. The surface mount LED assembly of claim 1, wherein the thermal mass reservoir is thermally coupled to the thermal contact pad.

8. A surface mount Light Emitting Diode (LED) assembly comprising:
a semiconductor package comprising:
a high performance LED device, and
a heat sink thermally coupled to the high performance LED device; and
a next level of assembly comprising:
a printed circuit board (PCB) having a first and a second surface and a cavity disposed therein;
a thermal contact pad disposed at least partially within the cavity and accessible from the first surface of the PCB; and
a thermal mass reservoir, disposed on the second surface of the PCB, and directly connected to the thermal contact pad,
wherein the thermal contact pad mechanically couples the semiconductor package to the next level assembly and directly connects the heat sink to the thermal mass reservoir.

9. The assembly of claim 8, wherein the thermal mass reservoir is a metal mass affixed to the second surface of the printed circuit board

10. The assembly of claim 8, wherein the thermal contact pad comprises a thermally conductive material.

11. The assembly of claim 8, wherein the thermal contact pad is substantially coplanar with a first metallization layer disposed on the first surface of the printed circuit board.

12. The assembly of claim 8, wherein the thermal contact pad comprises solder material.

13. The assembly of claim 8, further comprising a solder dam disposed about a periphery of the cavity.

14. A surface mount Light Emitting Diode (LED) assembly comprising:
a dielectric substrate having a first and a second surface;
a plurality of conductive circuit paths disposed on the first surface of the dielectric substrate;
a layer of copper cladding disposed on the second surface of the dielectric substrate;
a cavity disposed in the dielectric substrate and revealing a portion of the layer of copper cladding;
a barrier feature disposed about the periphery of the cavity; and
an LED device at least partially disposed in the cavity and electromechanically coupled to the conductive circuit paths.

15. The surface mount LED assembly of claim 14 wherein the LED device is affixed to the layer of copper cladding using a thermally conductive material.

16. The surface mount LED assembly of claim 15, wherein the LED device is soldered to the layer of copper cladding

17. A method of producing a surface mount Light Emitting Diode (LED) assembly with improved power dissipation comprising the steps of:
provisioning a high performance LED package with integrated heat sink;
provisioning a circuit substrate having a dielectric with first and second surfaces, said first surface having conductive traces, a cavity, and a solder darn disposed about a perimeter of the cavity, said second surface being covered at least in part with a layer of copper cladding, a portion of the copper cladding being exposed within the cavity;
depositing a thermal contact pad within the cavity, said thermal contact pad being directly connected to the layer of copper cladding; and
electromechanically coupling the high performance LED package to the circuit substrate, such that the integrated heat sink is thermally coupled to the layer of copper cladding via the thermal contact pad.

18. The method of claim 17, wherein the step of electromechanically coupling the high performance LED package to the PCB further comprises the step of soldering the integrated heat sink to a portion of the layer of copper cladding accessible through the cavity of the dielectric.

19. A method of producing a surface mount Light Emitting Diode (LED) assembly with improved power dissipation comprising the steps of:
provisioning a printed circuit board (PCB) having a first and a second surface, said first surface having conductive circuit paths, a cavity, and a barrier feature disposed about a periphery of the cavity, said second surface being covered at least in part with a layer of copper cladding, a portion of the copper cladding being exposed within the cavity;
directly attaching an LED die to the portion of the copper cladding exposed within the cavity; and
electromechanically coupling the LED die to the PCB conductive circuit paths.
